(19) United States
(12) Patent Application Publication
(10) Pub. No.: US 2013/0146345 A1
(43) Pub. Date: Jun. 13, 2013

(54) PRINTED WIRING BOARD AND METHOD FOR MANUFACTURING THE SAME

(71) Applicants: Kazuki KAJIHARA, Ogaki-shi (JP); Haruhiko MORITA, Ogaki-shi (JP)

(72) Inventors: Kazuki KAJIHARA, Ogaki-shi (JP); Haruhiko MORITA, Ogaki-shi (JP)

(21) Appl. No.: 13/664,906

(22) Filed: Oct. 31, 2012

Related U.S. Application Data
(60) Provisional application No. 61/569,348, filed on Dec. 12, 2011.

(51) Int. Cl. H05K 1/11; H05K 3/10; H05K 1/00

(52) U.S. Cl. 174/258; 174/250; 174/262; 174/264; 427/97.3; 427/97.4

(57) ABSTRACT

A printed wiring board includes a first insulation layer, a first conductive pattern formed on a first surface of the first insulation, a second conductive pattern formed on a second surface of the first insulation on the opposite side with respect to the first surface of the first insulation, a first buildup structure formed on the first surface of the first insulation and the first pattern, the first buildup structure including insulation layers and conductive patterns, and a second buildup structure formed on the second surface of the first insulation and the second pattern, the second buildup structure including insulation layers and conductive patterns. The second pattern and the patterns in the second buildup structure form an inductor, and the first and second patterns are positioned such that the distance between the first and second patterns in the thickness direction of the first insulation is set 100 μm or greater.

### CROSS-REFERENCE TO RELATED APPLICATIONS

The present application is based on and claims the benefit of priority to U.S. Application No. 61/569,348, filed Dec. 12, 2011, the entire contents of which are incorporated herein by reference.

### BACKGROUND OF THE INVENTION

1. Field of the Invention

The present invention relates to a printed wiring board where an inductor is formed in a buildup layer and a method for manufacturing such a printed wiring board.

2. Discussion of the Background

For mobile electronic devices such as cell phones and laptop computers, small low-voltage microprocessors with low drive voltage and low electricity consumption are used. Japanese Laid-Open Patent Publication No. 2009-16504 describes technology for forming an inductor in a wiring board by electrically connecting conductive patterns formed in different layers. The entire contents of this publication are incorporated herein by reference.

### SUMMARY OF THE INVENTION

According to one aspect of the present invention, a printed wiring board has a first insulation layer, a first conductive pattern formed on a first surface of the first insulation layer, a second conductive pattern formed on a second surface of the first insulation layer on the opposite side with respect to the first surface of the first insulation layer, a first buildup structure formed on the first surface of the first insulation layer and the first conductive pattern, the first buildup structure including insulation layers and conductive patterns, and a second buildup structure formed on the second surface of the first insulation layer and the second conductive pattern, the first buildup structure including insulation layers and conductive patterns. The second conductive pattern and the conductive patterns in the second buildup structure form an inductor, and the second conductive pattern and the first conductive pattern are positioned such that the distance between the second conductive pattern and the first conductive pattern in the thickness direction of the first insulation layer is set at 100 μm or greater.

According to another aspect of the present invention, a method for manufacturing a printed wiring board includes forming a first conductive pattern on a first surface of a first insulation layer, forming a second conductive pattern on a second surface of the first insulation layer on the opposite side with respect to the first surface of the first insulation layer, forming on the first surface of the first insulation layer and the first conductive pattern a first buildup structure including insulation layers and conductive patterns, and forming on the second surface of the first insulation layer and the second conductive pattern a second buildup structure including insulation layers and conductive patterns. The forming of the second conductive pattern and the forming of the conductive patterns of the second buildup structure include forming an inductor having the second conductive pattern and the conductive patterns of the second buildup structure, and the second conductive pattern and the first conductive pattern are formed such that the distance between the second conductive pattern and the first conductive pattern in the thickness direction of the first insulation layer is set at 100 μm or greater.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-(E) are views showing steps for manufacturing a printed wiring board according to a first embodiment;

FIGS. 2(A)-(D) are views showing steps for manufacturing a printed wiring board according to the first embodiment;

FIGS. 3(A)-(C) are views showing steps for manufacturing a printed wiring board according to the first embodiment;

FIGS. 4(A)-(C) are views showing steps for manufacturing a printed wiring board according to the first embodiment;

FIG. 5 is a cross-sectional view of the printed wiring board according to the first embodiment of the present invention;

FIG. 6 is a perspective view schematically showing positioning of a first conductive pattern and an inductor of the first embodiment;

FIG. 7 is a cross-sectional view of the printed wiring board according to the first embodiment;

FIG. 8 is a cross-sectional view of a printed wiring board according to a modified example of the first embodiment;

FIG. 9 is a cross-sectional view of a printed wiring board according to another modified example of the first embodiment;

FIG. 10(A) is a cross-sectional view schematically showing positioning of a first conductive pattern and an inductor in a printed wiring board according to a second embodiment; and

FIG. 10(B) is a perspective view schematically showing positioning of a first conductive pattern and an inductor in a printed wiring board according to the second embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

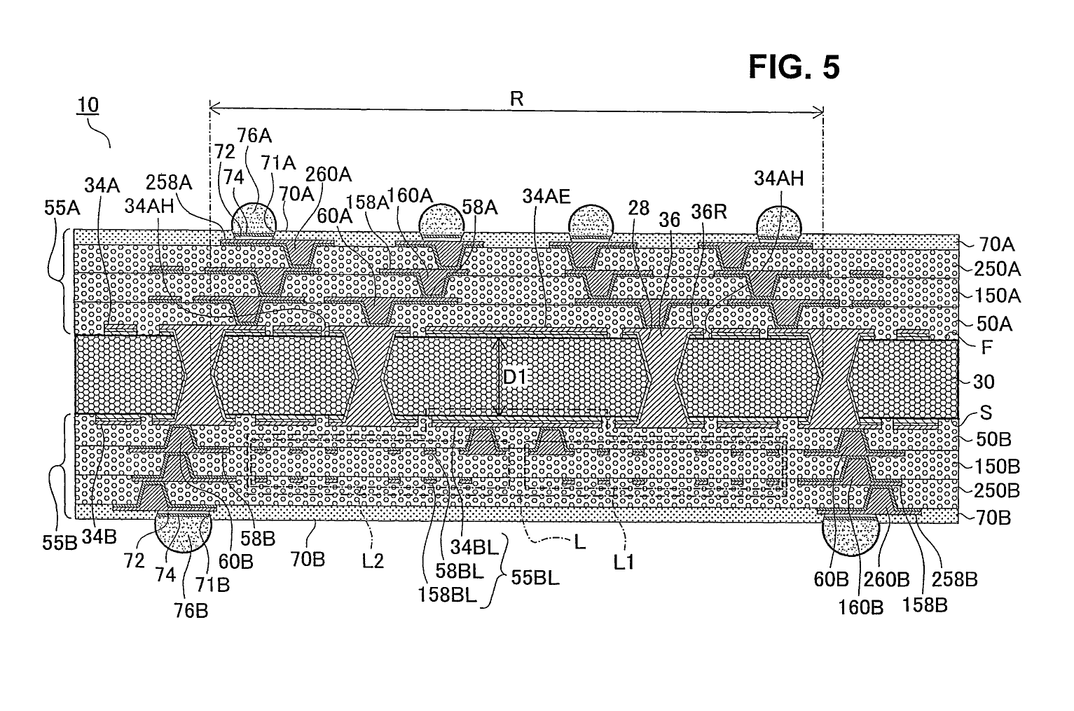

A printed wiring board according to a first embodiment of the present invention is described by referring to a cross-sectional view shown in FIG. 5.

Printed wiring board 10 includes first insulation layer 30 which has first surface (upper surface) (F) and its opposing second surface (lower surface) (S) along with penetrating hole 28. The maximum diameter of penetrating hole 28 is preferred to be 150 μm or less so that the number of later-described through-hole conductors 36 is increased. First insulation layer 30 contains reinforcing material made of any of the following: glass cloth, glass non-woven fabric, aramid cloth or aramid non-woven fabric.

First conductive pattern (34AE), which has multiple recessed portions (34AH), is formed on first surface (F) of first insulation layer 30. First conductive pattern (34A) is a plain pattern for power source or ground. Second conductive pattern (34BL) is formed on second surface (S) of first insulation layer 30. The detailed description of second conductive pattern (34BL) is provided later. Through-hole conductor 36 is formed by filling copper plating in penetrating hole 28 of first insulation layer 30. Then, land (36R) of through-hole conductor 36 is formed inside recessed portion (34AH) of first conductive pattern (34AE).

First buildup layer (55A) is formed on first surface (F) of first insulation layer 30 and on first conductive pattern (34AE). First buildup layer (55A) includes second insulation layers (50A, 150A, 250A) and third conductive patterns (58A, 158A, 258A) formed on their respective second insulation layers. Moreover, first buildup layer (55A) includes first via conductor (60A) which connects through-hole conductor 36 and third conductive pattern (58A), second via conductor (160A) which connects third conductive pattern (58A) and third conductive pattern (158A), and second via conductor (260A) which connects third conductive pattern (158A) and third conductive pattern (258A).

On second insulation layer (250A), solder-resist layer (70A) is formed, having opening portion (71A) which exposes at least part of third conductive pattern (258A). First bump (76A) is formed in opening portion (71A). A semiconductor element (omitted from the drawing) is mounted on printed wiring board 10 through first bump (76A).

Second buildup layer (55B) is formed on second surface (S) of first insulation layer 30 and on second conductive pattern (34BL). Second buildup layer (55B) includes third insulation layers (50B, 150B, 250B) and fourth conductive patterns (58B, 58BL, 158B, 158BL, 258B) formed on their respective third insulation layers.

Moreover, in third insulation layer (50B), second via conductor (60B) which connects second conductive pattern (34BL) and fourth conductive pattern (58BL), and second via conductor (60B) which connects through-hole conductor 36 and fourth conductor pattern (58B) are formed.

In third insulation layer (150B), a second via conductor (omitted from the drawing) which connects fourth conductive pattern (58BL) and fourth conductive pattern (158BL), as well as second via conductor (160B) which connects fourth conductive pattern (58B) and fourth conductive pattern (158B), is formed. In third insulation layer (250B), second via conductor (260B) is formed to connect fourth conductive pattern (158B) and fourth conductive pattern (258B). On third insulation layer (250B), solder-resist layer (70B), which includes opening portion (71B) to expose at least part of fourth conductive pattern (258B), is formed. Second bump (76B) is formed in opening portion (71B).

In second buildup layer (55B), inductor (L) is formed, being made up of second conductive pattern (34BL), fourth conductive patterns (58BL, 158BL), and a second via conductor (omitted from the drawing) which connects fourth conductive patterns (58BL, 158BL) to each other. Inductor (L) is formed in region (R) directly under the semiconductor element, namely, directly under region (R) where bumps (76A) are formed.

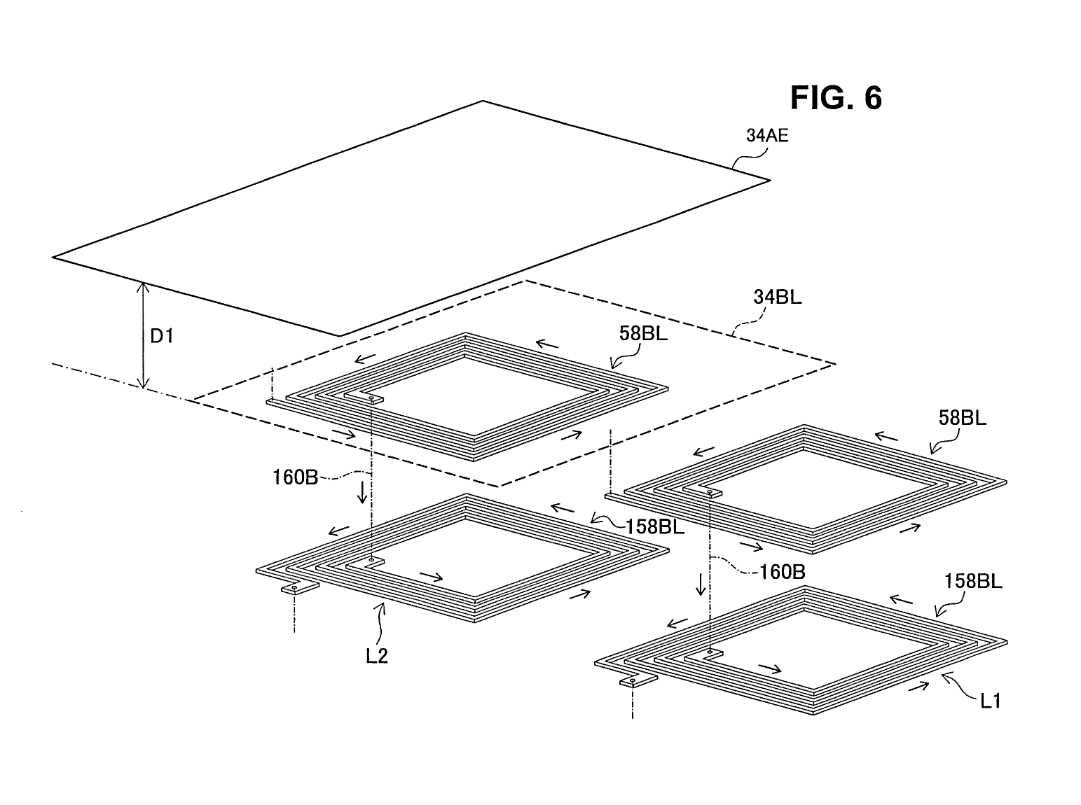

Fourth conductive patterns (58BL, 158BL) of inductor (L) are each formed in a spiral shape as shown in FIG. 6. Fourth conductive patterns (58BL, 158BL) are connected to each other by second via conductor (160B). In the present embodiment, a group of fourth conductive patterns (58BL, 158BL) connected by via conductors (160B) is referred to as inductor pattern (Ln) (n=1, 2, . . . ). The number of inductor patterns (Ln) is not limited specifically. In the present embodiment, eight inductor patterns are formed.

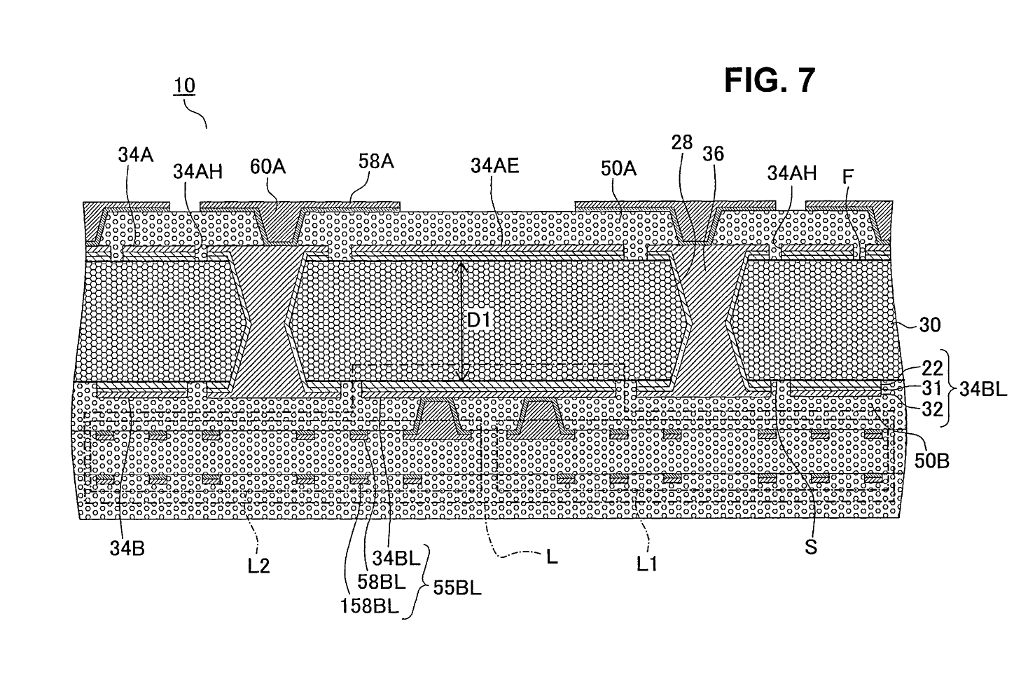

Second conductive pattern (34BL) of inductor (L) is a plain layer. As shown in FIG. 7, second conductive pattern (34BL) is formed with copper foil 22 on second surface (S) of first insulation layer 30, electroless plated film 31 on the copper foil, and electrolytic plated film 32 on electroless plated film 31. The thickness of second conductive pattern (34BL) is greater than the thickness of fourth conductive patterns (58BL, 158BL). By increasing the thickness of at least part of the conductive patterns of inductor (L) (second conductive pattern (34BL)), it is thought that the resistance of inductor (L) is reduced, making it easier to enhance the Q factor.

Above-described multiple inductor patterns (Ln) are each connected to second conductive pattern (34BL). Namely, multiple inductor patterns (Ln) are connected parallel. Accordingly, since electric current flowing in each of inductor patterns (Ln) is dispersed, the resistance in inductor (L) is thought to be reduced, making it easier to enhance the Q factor.

As shown in FIGS. 5 and 6, distance (D1) between inductor (L) and first conductive pattern (34AE) in a thickness direction is set at 100 μm or greater. Here, “distance (D1)” means the minimum distance in a thickness direction between second conductive pattern (34BL) of inductor (L) and first conductive pattern (34AE). When distance (D1) is 100 μm or greater, the blockage of the magnetic-field components generated from inductor (L) by first conductive pattern (34AE) is suppressed, making it easier to obtain the required inductance (for example, 4.0 nH or greater).

Here, when through-hole conductor 36 functions as part of inductor (L), for example, distance (D1) is preferred to be 1400 μm or less. In such a case, since the resistance of inductor (L) is suppressed from rising, the Q factor is suppressed from lowering. Moreover, distance (D1) is especially preferred to be 250 μm or less. In such a case, voids are suppressed from occurring when plating is filled in penetrating hole 28 in first insulation layer 30, and the resistance of inductor (L) is suppressed from rising. As a result, it is even easier to suppress the Q factor from lowering.

Bumps (76B) are not formed in the region directly under inductor (L). Therefore, the blockage of the magnetic-field components generated from inductor (L) by bumps (76B) is suppressed, making it even easier to obtain the required inductance.

An LC filter is formed by inductor (L) of the present embodiment and a capacitor not shown in the drawings. Such an LC filter is preferred to be formed in the region directly under the semiconductor element. In such a case, voltage is instantly supplied to the semiconductor element without incurring much loss.

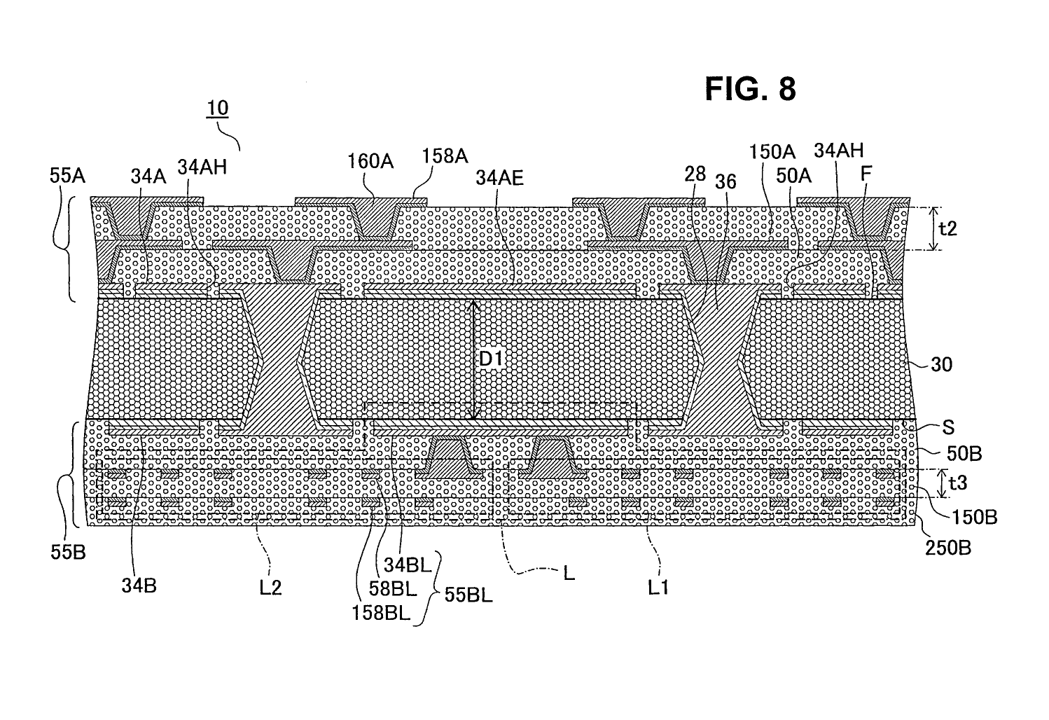

Alternatively, as shown in FIG. 8, it is an option to set thickness (t3) of third insulation layer (150B) of second buildup layer (55B) to be smaller than thickness (t2) of second insulation layer (150A) of first buildup layer (55A). In such a case, in the region directly under the semiconductor element, the difference decreases between the rate of conductors on the first-surface (F) side of first insulation layer 30 (a so-called remaining copper rate) and the rate of conductors on the second-surface (S) side of first insulation layer 30 (remaining copper rate), making it easier to suppress warping of printed wiring board 10. In addition, since the depth of a second via conductor (not shown in the drawings) which penetrates through third insulation layer (150B) becomes shallower, the Q factor is thought to be enhanced. In such a case, whether third insulation layers (50B, 150B, 250B) of second buildup layer (55B) are all set thinner than second insulation layer (150A), or whether not all of the third insulation layers are set thinner, may be determined appropriately from the viewpoint of adjusting the remaining copper rates.

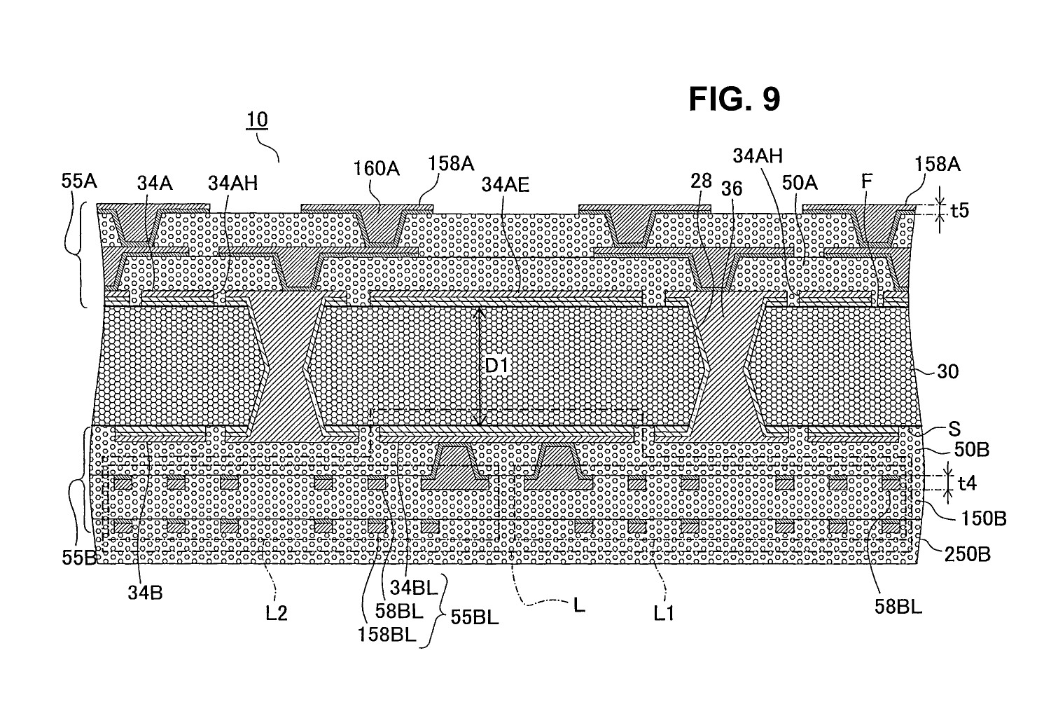

Also, thickness (T4) of fourth conductive pattern (158BL) of second buildup layer (55B) may be set greater than thickness (T5) of third conductive pattern (158A) of first buildup layer (55A) as shown in FIG. 9. In such a case, warping of printed wiring board 10 tends to be suppressed. In addition, the Q factor is thought to be enhanced. In such a case, whether fourth conductive patterns (58BL, 158BL) of second buildup layer (55B) are all set greater than third conductive pattern (158A), or whether not all of the fourth conductive patterns are set greater, may be determined appropriately from the viewpoint of adjusting the remaining copper rates.

Also, to suppress warping of printed wiring board 10, the above-described reinforcing material may be contained in either second insulation layers (50A, 150A) of first buildup layer (55A) or third insulation layers (50B, 150B) of second buildup layer (55B). In such a case, it is preferred that reinforcing material be contained only in second insulation layer (50A) which is in contact with first surface (F) of first insulation layer 30, and third insulation layer (50B) which is in contact with second surface (S) of first insulation layer 30, so that fine conductive patterns are also achieved.

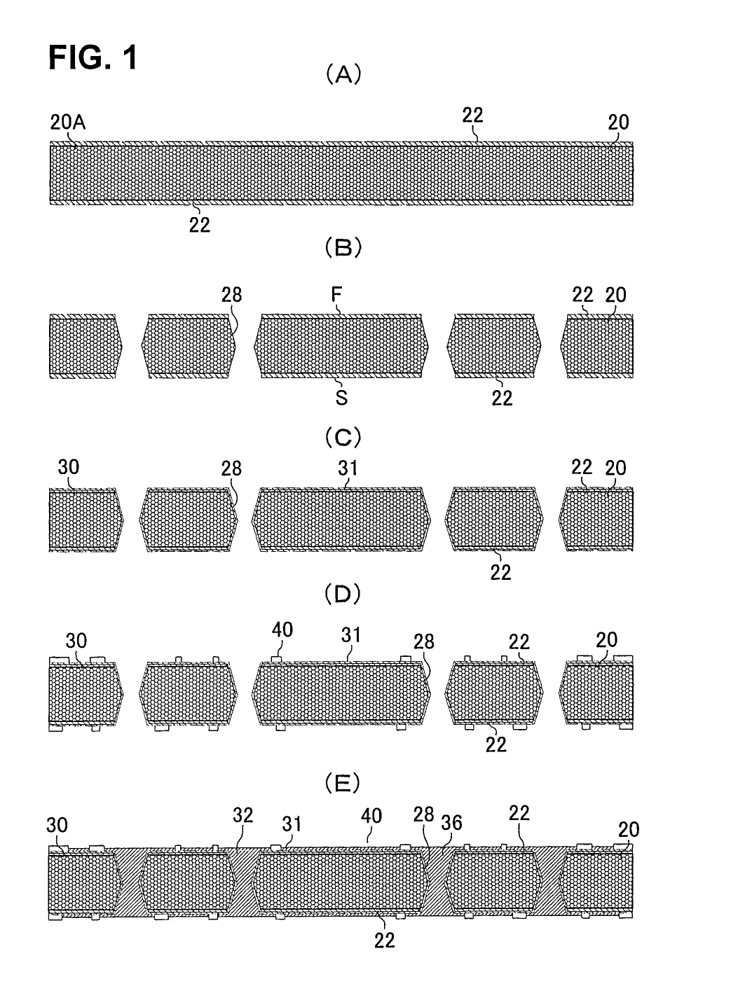

In the following, a method for manufacturing printed wiring board 10 described above with reference to FIG. 5 is described by referring to FIGS. 1-4.

(1) Copper-clad laminate (20A) is prepared with the following: substrate 20 (first insulation layer) made of glass-epoxy resin or BT (bismaleimide triazine) resin with an approximate thickness of 250 μm; and copper foil 22 with an approximate thickness of 15 μm laminated on both surfaces of substrate 20. A black-oxide treatment is conducted on the surface of copper foil 22 (FIG. 1(A)).

(2) A laser is irradiated from the first-surface (upper-surface) (F) side and the second-surface (lower-surface) (S) side of substrate 20 to form penetrating holes 28 for through-hole conductors (FIG. 1(B)).

(3) After a desmearing treatment is conducted on penetrating holes 28, electroless plated film 31 is formed by performing electroless plating (FIG. 1(C)).

(4) Plating resist 40 is formed on electroless plated film 31 on the substrate surfaces. Plating resist 40 has openings corresponding to where conductive patterns are to be formed (FIG. 1(D)).

(5) Electrolytic plated film 32 is formed in the openings of plating resist 40 and in penetrating holes 28 (FIG. 1(E)).

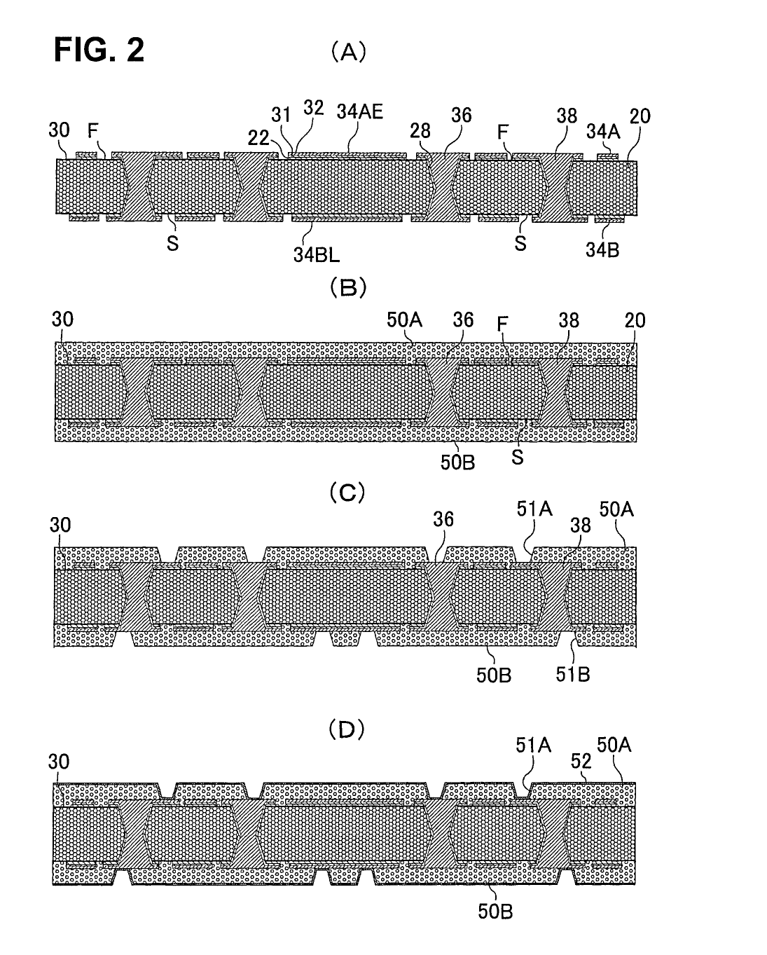

(6) Electroless plated film and copper foil exposed after plating resist 40 has been removed are etched away. Accordingly, through-hole conductors 36 are formed, first conductive pattern (34A) is formed on the first-surface (F) side, and second conductive pattern (34BL) is formed on the second-surface (S) side (FIG. 2(A)).

(7) Second insulation layer (50A) with an approximate thickness of 30 μm is formed on first surface (F) of first insulation layer 30, while third insulation layer (50B) with an approximate thickness of 30 μm is formed on second surface (S) of first insulation layer 30 (FIG. 2(B)).

(8) Using a CO2 gas laser, openings (51A, 51B) for via conductors with an approximate diameter of 50 μm are formed respectively in insulation layers (50A, 50B) (FIG. 2(C)). Using an oxidation agent or the like, surfaces of insulation layers (50A, 50B) are roughened (not shown in the drawings).

(9) A catalyst such as palladium is attached in advance to surfaces of insulation layers (50A, 50B), and the substrate is immersed in an electroless plating solution for 5˜60 minutes so that electroless plated film 52 is formed (FIG. 2(D)).

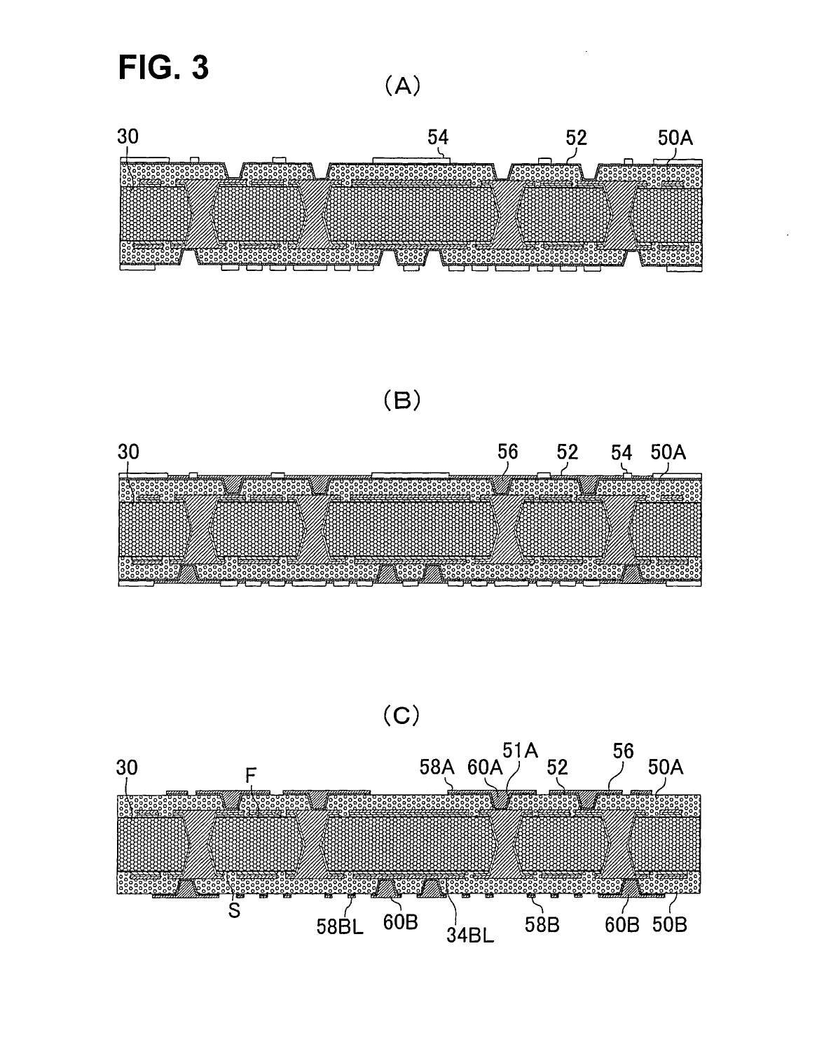

(10) Plating resist 54 with a predetermined pattern is formed on substrate 30 after the above treatment (FIG. 3(A)).

(11) Next, electrolytic plating is performed to form electrolytic plated film 56 (FIG. 3(B)).

(12) Plating resist 54 is removed, and electroless plated film 52 under the plating resist is dissolved and removed. Accordingly, third conductive patterns (58A) made of electroless plated film 52 and electrolytic plated film 56 are formed on second insulation layer (50A). First via conductors (60A) are formed in second insulation layer (50A). Moreover, inductor patterns (fourth conductive patterns) (58BL) are formed on third insulation layer (50B) (FIG. 3(C)). Second via conductors (60B) are formed in third insulation layer (50B) to connect second conductive pattern (34B) and inductor patterns (fourth conductive patterns) (58BL). Then, an etching solution is used to roughen the surface of each conductive pattern including inductor patterns (fourth conductive patterns) (58BL) (not shown in the drawings).

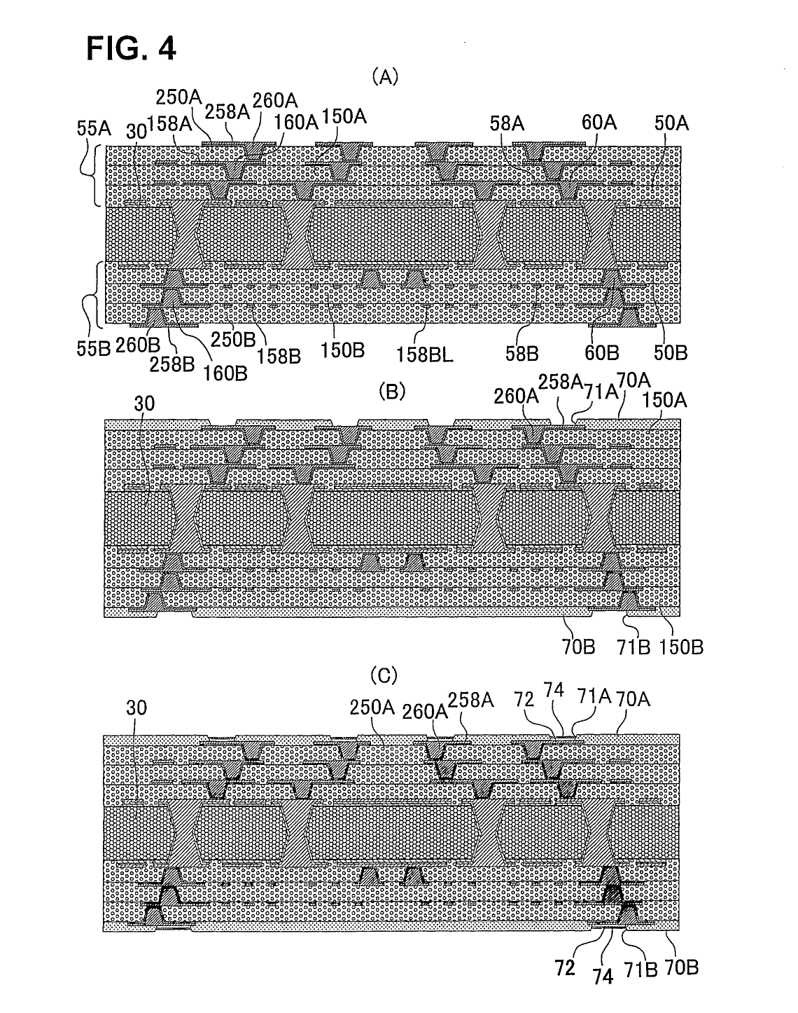

(13) In the same manner as in above steps (7)˜(12), first buildup layer (55A) having third conductive patterns (158A, 258A) and second buildup layer (55B) having inductor patterns (fourth conductive patterns) (158BL) are formed (FIG. 4(A)).

(14) Next, a commercially available solder-resist composition is applied, exposed to light and developed so that solder-resist layers (70A, 70B) having openings (71A, 71B) are formed (FIG. 4(B)).

(15) Electroless nickel plating is performed to form nickel-plated layer 72 in openings (71A, 71B). Moreover, gold plating is performed to form gold-plated layer 74 on nickel-plated layer 72 (FIG. 4(C)). Nickel-gold layers may be substituted with nickel-palladium-gold layers.

(16) Then, solder balls are loaded in openings (71A, 71B), and a reflow is conducted. Accordingly, solder bumps (76A) are formed on the first-surface (upper-surface) side and solder bumps (76B) are formed on the second-surface (lower-surface) side to complete printed wiring board 10 (FIG. 5).

### Second Embodiment

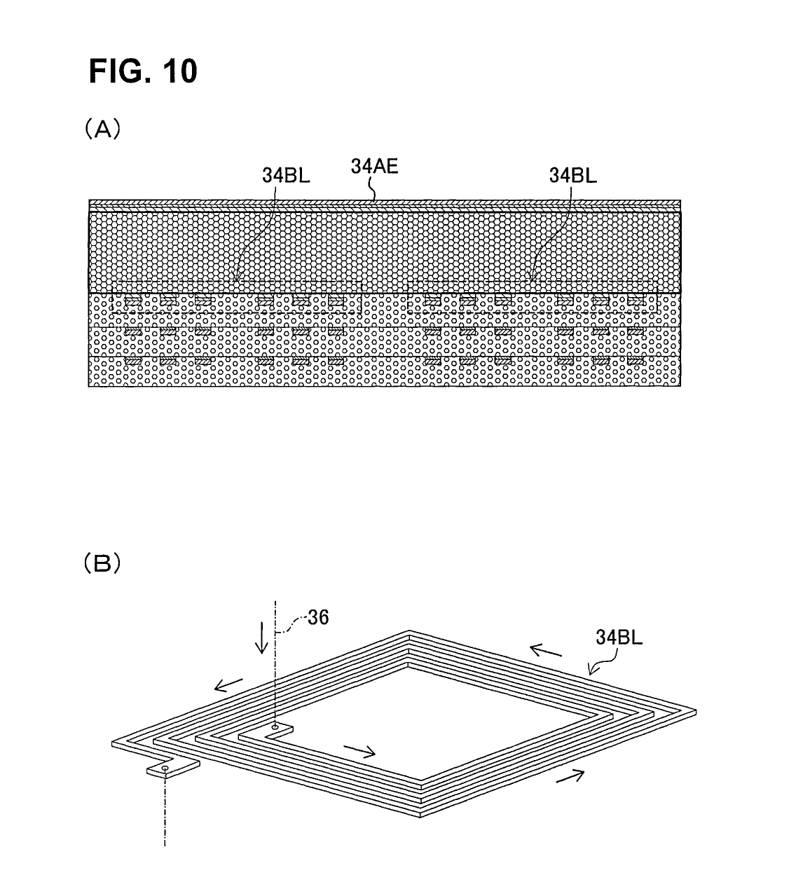

Second conductive pattern (34BL) of inductor (L) is set as a plain layer in the above-described first embodiment; however, it may also be a spiral pattern as shown in FIG. 10. Namely, multiple spiral inductor patterns (34BL) are also formed on second surface (S) of first insulation layer 30. In such a case, conductive pattern (34AE) on first surface (F) of first insulation layer 30 and spiral inductor patterns (34BL) (second conductive patterns) are connected by through-hole conductors 36. Then, the same effects as in the above-described first embodiment are also achieved in the printed wiring board of the present embodiment.

### Third Embodiment

In the above-described first embodiment, the surface where the semiconductor element is positioned is set as first surface (F) of first insulation layer 30. It is set as second surface (S) in a third embodiment. Namely, the surface of first insulation layer 30 (the surface where the semiconductor element is positioned) is second surface (S), and inductor (L) is formed in a second buildup layer on second surface (S). The same effects as in the above-described first embodiment are also achieved in the printed wiring board of the present embodiment.

### Example 1

In Example 1, the thickness of first insulation layer 30 is set at 400 μm, the diameter of a through hole at 180 μm, the diameter of a through-hole land at 330 μm, the diameter of a via conductor at 60 μm, the diameter of a via land at 84 μm, the thicknesses of first and second insulation layers at 25 μm, and the number of turns of inductor patterns at 3. As a result of simulating the structure set in Example 1, the inductance value of the inductor at 50 MHz was 5.64 nH and the Q factor was 17.0. Required electrical characteristics were satisfied.

### Example 2

In Example 2, the thickness of first insulation layer 30 is set at 250 μm, the diameter of a through hole at 100 μm, the diameter of a through-hole land at 200 μm, the diameter of a via conductor at 60 μm, the diameter of a via land at 84 μm, the thicknesses of interlayer resin insulation layers at 25 μm, and the number of turns of inductor patterns at 3. As a result of simulating the structure set in Example 2, the inductance value of the inductor at 50 MHz was 5.54 nH and the Q factor was 16.0. Required electrical characteristics were satisfied.

### Example 3

In Example 3, the thickness of first insulation layer 30 is set at 100 μm, the diameter of a through hole at 100 μm, the diameter of a through-hole land at 200 μm, the diameter of a via conductor at 60 μm, the diameter of a via land at 84 μm, the thicknesses of interlayer resin insulation layers at 25 μm, and the number of turns of inductor patterns at 3. As a result of simulating the structure set in Example 3, the inductance value of the inductor at 50 MHz was 4.55 nH and the Q factor was 11.7. Required electrical characteristics were satisfied.

### Comparative Example 1

In Comparative Example 1, the thickness of first insulation layer 30 is set at 80 μm, the diameter of a through hole at 100 μm, the diameter of a through-hole land at 200 μm, the diameter of a via conductor at 60 μm, the diameter of a via land at 84 μm, the thicknesses of interlayer resin insulation layers at 25 μm, and the number of turns of inductor patterns at 3. As a result of simulating the structure set in Comparative Example 1, the inductance value of the inductor at 50 MHz was 3.12 nH and the Q factor was 5.76. Required electrical characteristics were not satisfied.

When the thickness of a wiring board is significantly thin, and the number of layers for conductive patterns is small, space for forming an inductor is limited. Accordingly, inductance to be obtained is limited. Moreover, due to interference with other conductive patterns, magnetic-field components generated from the inductor are weakened, and the required inductance may not be achieved. As described, when the thickness of a wiring board is significantly thin, and the number of layers for conductive patterns is small, it may be difficult to achieve the required inductance and Q factor.

According to an embodiment of the invention, a printed wiring board has the following: a first insulation layer having a first surface and a second surface opposite the first surface; a first conductive pattern formed on the first surface of the first insulation layer; a second conductive pattern formed on the second surface of the first insulation layer; a first buildup layer formed on the first surface of the first insulation layer and on the first conductive pattern and having multiple second insulation layers and third conductive patterns formed on the second insulation layers; and a second buildup layer formed on the second surface of the first insulation layer and on the second conductive pattern and having multiple third insulation layers and fourth conductive patterns formed on the third insulation layers. Such a printed wiring board has the following technological features: an inductor is formed with the second conductive pattern and the fourth conductive patterns; and the distance between the second conductive pattern of the inductor and the first conductive pattern in a thickness direction is set at 100 μm or greater.

According to another embodiment of the present invention, a method for manufacturing a printed wiring board includes the following: preparing a first insulation layer having a first surface and a second surface opposite the first surface; forming a first conductive pattern on the first surface of the first insulation layer; forming a second conductive pattern on the second surface of the first insulation layer; on the first surface of the first insulation layer and on the first conductive pattern, forming a first buildup layer which has a plurality of second insulation layers and third conductive patterns formed on the second insulation layers; and on the second surface of the first insulation layer and on the second conductive pattern, forming a second buildup layer which has a plurality of third insulation layers and fourth conductive patterns formed on the third insulation layers. Such a manufacturing method has the following technological features: an inductor is formed with the second conductive pattern and the fourth conductive patterns; and the distance between the second conductive pattern of the inductor and the first conductive pattern in a thickness direction is set at 100 μm or greater.

In a printed wiring board according to an embodiment of the present invention, a first conductive pattern is formed on the first-surface side of the first insulation layer, and an inductor is formed on the opposing second-surface side. Here, magnetic-field components generated from the inductor are thought to be blocked by the surrounding conductive patterns (such as the first conductive pattern). However, the distance between the first conductive pattern and the inductor (the minimum distance in a thickness direction) is set to have a required value (100 μm or greater) according to the embodiment of the present invention. Accordingly, the blockage of the magnetic-field components generated from the inductor by the first conductive pattern is suppressed.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a first insulation layer;
a first conductive pattern formed on a first surface of the first insulation layer;
a second conductive pattern formed on a second surface of the first insulation layer on an opposite side with respect to the first surface of the first insulation layer;
a first buildup structure formed on the first surface of the first insulation layer and the first conductive pattern, the first buildup structure comprising a plurality of insulation layers and a plurality of conductive patterns; and
a second buildup structure formed on the second surface of the first insulation layer and the second conductive pattern, the second buildup structure comprising a plurality of insulation layers and a plurality of conductive patterns,
wherein the second conductive pattern and the plurality of conductive patterns in the second buildup structure form an inductor, and the second conductive pattern and the first conductive pattern are positioned such that the distance between the second conductive pattern and the first conductive pattern in a thickness direction of the first insulation layer is set at 100 μm or greater.

2. The printed wiring board according to claim 1, wherein the second conductive pattern and the first conductive pattern are positioned such that the distance between the second conductive pattern and the first conductive pattern in the thickness direction of the first insulation layer is set at 250 μm or less.

3. The printed wiring board according to claim 1, wherein the first conductive pattern is a plane conductive layer connected to one of a power source line and a ground line.

4. The printed wiring board according to claim 1, wherein the second conductive pattern is a plane conductive layer.

5. The printed wiring board according to claim 1, wherein the first buildup structure includes a plurality of first bumps positioned to mount a semiconductor device, the plurality of conductive patterns in the first buildup structure includes an outermost conductive pattern, and the plurality of first bumps is formed on the outermost conductive patterns in the first buildup structure such that the inductor is formed directly under a region in which the plurality of first bumps is formed.

6. The printed wiring board according to claim 1, wherein the plurality of conductive patterns in the second buildup structure includes an outermost conductive pattern, the second buildup structure includes a plurality of second bumps formed on the outermost conductive pattern in the second buildup layer, and the plurality of second bumps is positioned such that the plurality of second bumps is not formed in a region in which the inductor is directly underneath.

7. The printed wiring board according to claim 1, further comprising a through-hole conductor formed through the first insulation layer, wherein the first insulation layer has a penetrating hole extending from the first surface to the second surface, and the through-hole conductor comprises a plating material filling the penetrating hole of the first insulation layer.

8. The printed wiring board according to claim 7, wherein the penetrating hole has a diameter set in a range of 150 μm or less.

9. The printed wiring board according to claim 1, wherein the first insulation layer has a reinforcing material made of an inorganic fiber.

10. The printed wiring board according to claim 1, wherein the plurality of insulation layers of the second buildup structure has a reinforcing material made of an inorganic fiber.

11. A method for manufacturing a printed wiring board, comprising:
forming a first conductive pattern on a first surface of a first insulation layer;
forming a second conductive pattern on a second surface of the first insulation layer on an opposite side with respect to the first surface of the first insulation layer;
forming on the first surface of the first insulation layer and the first conductive pattern a first buildup structure comprising a plurality of insulation layers and a plurality of conductive patterns; and
forming on the second surface of the first insulation layer and the second conductive pattern a second buildup structure comprising a plurality of insulation layers and a plurality of conductive patterns,
wherein the forming of the second conductive pattern and the forming of the plurality of conductive patterns of the second buildup structure comprise forming an inductor comprising the second conductive pattern and the plurality of conductive patterns of the second buildup structure, and the second conductive pattern and the first conductive pattern are formed such that the distance between the second conductive pattern and the first conductive pattern in a thickness direction of the first insulation layer is set at 100 μm or greater.

12. The method for manufacturing the printed wiring board according to claim 11, wherein the second conductive pattern and the first conductive pattern are formed such that the distance between the second conductive pattern and the first conductive pattern in the thickness direction of the first insulation layer is set at 250 μm or less.

13. The method for manufacturing the printed wiring board according to claim 11, wherein the forming of the first conductive pattern comprises forming a plane conductive layer configured to be connected to one of a power source line and a ground line.

14. The method for manufacturing the printed wiring board according to claim 11, wherein the forming of the second conductive pattern comprising forming a plane conductive layer.

15. The method for manufacturing the printed wiring board according to claim 11, wherein the forming of the first buildup structure includes forming a plurality of first bumps positioned to mount a semiconductor device, the plurality of conductive patterns in the first buildup structure includes an outermost conductive pattern, and the plurality of first bumps is formed on the outermost conductive patterns in the first buildup structure such that the inductor is formed directly under a region in which the plurality of first bumps is formed.

16. The method for manufacturing the printed wiring board according to claim 11, wherein the plurality of conductive patterns in the second buildup structure includes an outermost conductive pattern, the forming of the second buildup structure includes forming a plurality of second bumps on the outermost conductive pattern in the second buildup layer, and the plurality of second bumps is positioned such that the plurality of second bumps is not formed in a region in which the inductor is directly underneath.

17. The method for manufacturing the printed wiring board according to claim 11, further comprising:
forming a penetrating hole through the first insulation layer such that the penetrating hole extends from the first surface to the second surface of the first insulation layer; and
filling a plating material into the penetrating hole in the first insulation layer such that a through-hole conductor is formed through the first insulation layer.

18. The method for manufacturing the printed wiring board according to claim 17, wherein the forming of the penetrating hole comprises forming the penetrating hole having a diameter set in a range of 150 μm or less.

19. The method for manufacturing the printed wiring board according to claim 11, further comprising preparing the first insulation layer comprising a reinforcing material made of an inorganic fiber.

20. The method for manufacturing the printed wiring board according to claim 11, wherein the forming of the second buildup structure includes forming the insulation layers comprising reinforcing materials made of inorganic fibers.
